(19) United States
(12) Patent Application Publication
(10) Pub. No.: US 2021/0333666 A1
(43) Pub. Date: Oct. 28, 2021

(54) ARRAY SUBSTRATE AND LIQUID CRYSTAL DISPLAY PANEL

(71) Applicant: Shenzhen China Star Optoelectronics Technology Co., Ltd., Shenzhen (CN)

(72) Inventor: Na Liu, Shenzhen (CN)

(21) Appl. No.: 16/319,465

(22) PCT Filed: Dec. 13, 2018
(86) PCT No.: PCT/CN2018/120986

§ 371 Date: Jan. 21, 2019

(30) Foreign Application Priority Data
Oct. 23, 2018 (CN) 201811240132.6

(51) Int. Cl. G02F 1/1362; G02F 1/1368; G02F 1/1335; G02F 1/1339; H01L 27/12

(52) U.S. Cl. CPC G02F 1/136227; G02F 1/1368; H01L 27/124; G02F 1/136286; G02F 1/1339; G02F 1/133512

(57) ABSTRACT

An array substrate and a liquid crystal display panel are disclosed. In each pixel unit of the array substrate of the present invention, the gate electrode of the thin-film transistor and the via hole for connecting the thin-film transistor and the pixel electrode are respectively located at two sides of the two adjacent data lines closed to the pixel unit. Thereby, the present invention can significantly reduce the aperture ratio difference between the two sides of the pixel unit. Without affecting the aperture ratio, the difference in viewing angle due to the difference in aperture ratio is effectively solved, and the display quality is improved.

### FIELD OF THE INVENTION

The present invention relates to a display technology field, and more particularly to an array substrate and a liquid crystal display panel.

### BACKGROUND OF THE INVENTION

The Liquid Crystal Display (LCD) has many advantages such as thin body, power saving, no radiation, etc., so that the LCD has been widely applied. For example, the LCD TV, the mobile phone, the personal digital assistant (PDA), the digital camera, the computer screen or the laptop screen dominates the field of flat panel display.

Most of the liquid crystal displays on the market are backlight type liquid crystal displays, which include a liquid crystal display panel and a backlight module. The operation principle of the liquid crystal display panel is to fill liquid crystal molecules between a Thin-Film Transistor Array Substrate (TFT Array Substrate) and a Color Filter (CF), and apply a driving voltage on the two substrates. To control the rotation direction of the liquid crystal molecules to refract the light of the backlight module to produce a picture.

In the prior art, the array substrate is generally provided with multiple scanning lines, multiple data lines, and a common electrode line. The scanning lines and the common electrode lines are both located at a first metal layer, and the data lines are located at a second metal layer above the first metal layer. The color filter substrate generally comprises a black matrix, red resists, green resists, blue resists, common electrodes and spacers (PS), and the spacers are used to maintain a uniform gap between the array substrate and the color filter substrate.

The existing liquid crystal display panel adopting the technology of COA (a color resist layer formed on a side of the array substrate) generally has TFT devices arranged as a matrix, multiple data lines, and multiple scanning lines to form an array substrate and the color resist layer is formed on the array substrate. When the array substrate on which the color resist layer is formed and the color filter substrate are aligned and assembled, the spacer is disposed at a location corresponding to the TFT device, and the TFT can be protected due to the existence of the color resist layer in order to prevent against the influence of spacer movement and extrusion on the electrical properties of the TFT device.

However, for a non-COA-designed liquid crystal display panel, there is no color resist layer as a protective layer between the spacer and the array substrate. In this case, if the spacer is still disposed corresponding to the TFT device, the TFT electrical property may be affected. Therefore, for a display panel that is not designed by COA, the spacer can only be disposed corresponding to the scanning line. To ensure that when the spacer substrate and the color filter substrate are misaligned, the spacer can still has the supporting function accurately, a width of the scanning line needs to be added, which affects the aperture ratio of the pixel.

In order to maximize the aperture ratio of the pixel, referring to FIG. 1, a conventional array substrate includes multiple scanning lines 1100 and multiple data lines 2100, and the multiple scanning lines 1100 and the multiple data lines 2100 are intersected to form multiple pixel units arranged as a matrix. Each pixel unit includes a thin-film transistor T′ and a pixel electrode 3000. The thin-film transistor T′ includes a gate electrode 1200, a source electrode 2200, and a drain electrode 2300. The gate electrodes 1200 of the thin-film transistors T′ of a row of the pixel units are connected to one scanning line 1100. The drain electrodes 2300 of the thin-film transistor T′ of a column of the pixel units are connected to one data line 2100. The source electrode 2200 of each thin-film transistor T′ is connected to the pixel electrode 3000 where the pixel unit is located through a via hole 9001. And in each pixel unit, the gate electrode 1200 and the via hole 9001 of the thin-film transistor T′ are located on the same side of the pixel unit.

When the array substrate and the color filter substrate are aligned and assembled to obtain a liquid crystal display panel, referring to FIG. 2, the black matrix 5000 on the color filter substrate needs to cover the scanning line 1100, the data line 2100, and the thin-film transistor T′ except a connection portion with the pixel electrode 3000 is provided with a spacer on a portion other than the portion where the scanning line 1100 is intersected with the data line 2100 between the color filter substrate and the array substrate. The array substrate with the above structure can ensure that the spacer will not affect the electric property of the TFT device such that the aperture ratio of the sub-pixels is maximized. However, the aperture ratios on both sides of one pixel region of the array substrate of the structure are different. As shown in FIG. 2, the aperture ratio on the left side of the pixel region is significantly smaller than the aperture ratio on the right side. When the liquid crystal display having the array substrate is driven by a column inversion method, the transmittances on both sides of the pixel region are different, and thus the differences in viewing angles are generated and affect display quality.

### SUMMARY OF THE INVENTION

An object of the present invention to provide an array substrate having a high aperture ratio and capable of eliminating the difference in viewing angle.

Another object of the present invention to provide a liquid crystal panel having a high aperture ratio and capable of eliminating the difference in viewing angle.

In order to achieve the above purpose, the present invention first provides with an array substrate, comprising: multiple scanning lines and multiple data lines, wherein the multiple scanning lines and the multiple data lines are intersected to form multiple pixel units arranged as a matrix; wherein each pixel unit includes a thin-film transistor and a pixel electrode, the thin-film transistor includes a gate electrode, a source electrode, and a drain electrode, the gate electrodes of the thin-film transistors of a row of the pixel units are correspondingly connected to one scanning line, one of the source electrode and the drain electrode of each thin-film transistor of a column of the pixel units is correspondingly connected to one data line, and the other of the source electrode and the drain electrode of each thin-film transistor is connected to a pixel electrode of the pixel unit through a via hole; wherein in each pixel unit, the gate electrode and the via hole of the thin-film transistor are respectively located at two sides of two adjacent data lines closed to the pixel unit.

Wherein the thin-film transistor further includes an active pattern; in each thin-film transistors, the active pattern is disposed on the gate electrode, and the source electrode and the drain electrode are respectively connected to two ends of the active pattern.

Wherein in each pixel unit, one end of the drain electrode of the thin-film transistor is connected to one end of the active pattern, and the other end is connected to the corresponding data line, one end of the source electrode is connected to the other end of the active pattern, and the other end extends to one of the two data lines adjacent to the pixel unit away from the gate electrode of the thin-film transistor, and is connected to the pixel electrode of the pixel unit through the via hole.

Wherein the source electrode includes a first portion, a second portion, and a connection end which are sequentially connected; the first portion is connected to the active pattern and extends along a direction parallel to the data line; the second portion extends along a direction parallel to the scanning line; the via hole corresponds to the connection end.

Wherein the drain electrode includes a third portion and a fourth portion which are sequentially connected; the third portion is connected to the active pattern and extends in a direction away from the active pattern; the fourth portion extends along a direction parallel to the scanning line and connects the third portion with the corresponding data line.

Wherein the array substrate includes a first metal layer and a second metal layer disposed above and insulated from the first metal layer; the multiple scanning lines and the gate electrodes of the thin-film transistors of the multiple pixel units are all located at the first metal layer; the multiple data lines and the source electrodes and the drain electrodes of the thin-film transistors of the multiple pixel units are both located at the second metal layer.

Wherein a width of an overlapping portion of the scanning line and the data line is less than a width of a portion of the scanning line except the overlapping portion with the data line.

The present invention also provides a liquid crystal display panel, comprising: the array substrate as described above; and a color filter substrate disposed opposite to the array substrate.

Wherein the color filter substrate includes a black matrix, and the black matrix is disposed opposite to the multiple scanning lines, the multiple data lines, and the multiple thin-film transistors, and at least partially exposes a connection portion of the thin-film transistor and the pixel electrode.

Wherein the liquid crystal display panel further includes multiple spacers disposed between the array substrate and the color filter substrate, and the multiple spacers correspond to a portion of the scanning lines except a portion overlapped with the data lines; a projection of the spacer on the scanning line is located at an inner edge of the scanning line.

In summary, in each pixel unit of the array substrate of the present invention, the gate electrode of the thin-film transistor and the via hole for connecting the thin-film transistor and the pixel electrode 300 are respectively located at two sides of the two adjacent data lines closed to the pixel unit. Accordingly, without affecting the aperture ratio, the difference in viewing angle due to the difference in aperture ratio is effectively solved, and the display quality is improved. The liquid crystal display panel of the present invention has a high aperture ratio and can eliminate the difference in viewing angle.

### BRIEF DESCRIPTION OF THE DRAWINGS

In order to further understand the features and technical contents of the present invention, please refer to the following detailed description and drawings regarding the present invention. The drawings are provided for purposes of illustration and description only and are not intended for limiting.

In the drawings,

FIG. 1 is a top plan view of an array substrate using non-COA technology in the conventional art;

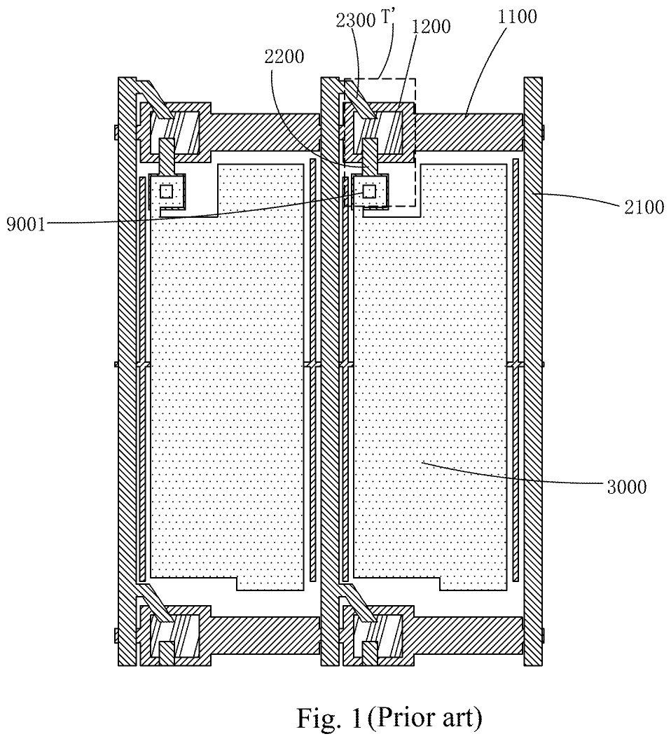

FIG. 2 is a schematic diagram of the array substrate and the color filter substrate after being aligned and assembled shown in FIG. 1 and covered by a black matrix of the color filter substrate;

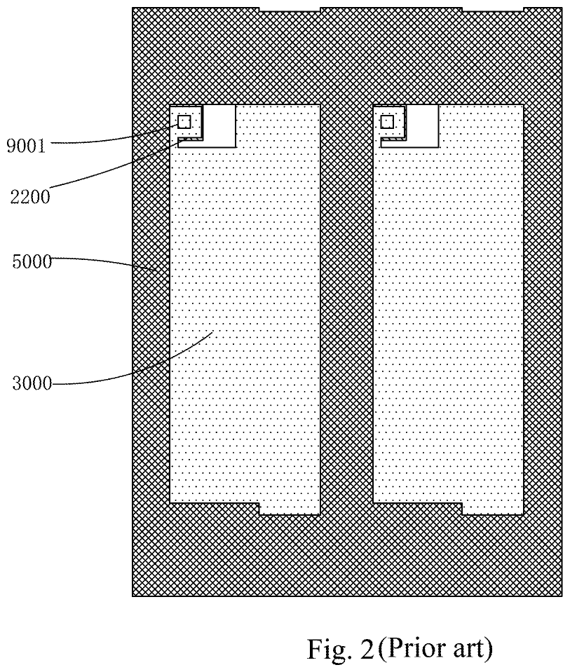

FIG. 3 is a top plan view of an array substrate of the present invention;

FIG. 4 is a top plan view of a scanning line, a data line, and a thin-film transistor of the array substrate of the present invention;

FIG. 5 is a schematic diagram of a spacer disposed corresponding to the scanning line of the liquid crystal display panel of the present invention; and

FIG. 6 is a schematic diagram of the arrangement of a black matrix of a liquid crystal display panel of the present invention.

### DETAILED DESCRIPTION OF PREFERRED EMBODIMENTS

In order to further illustrate the technical means and effects of the present invention, the following detailed description will be made in conjunction with the preferred embodiments of the invention and the accompanying drawings.

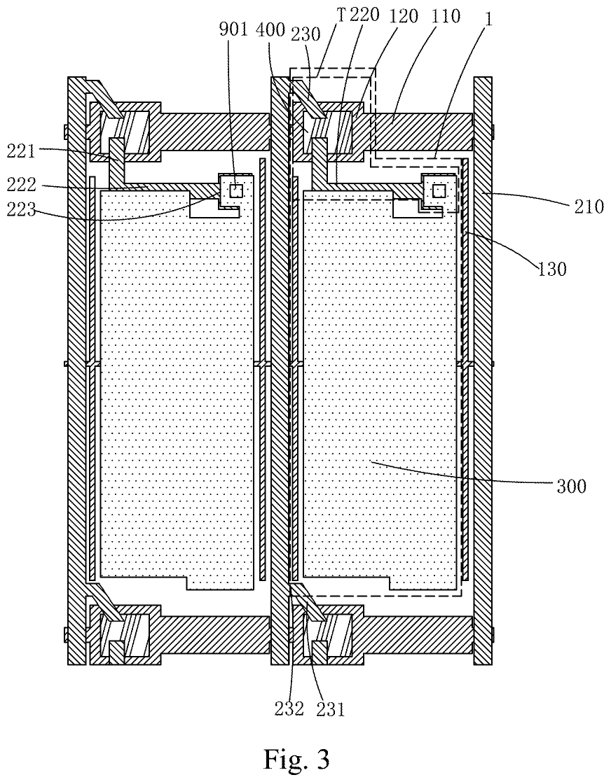

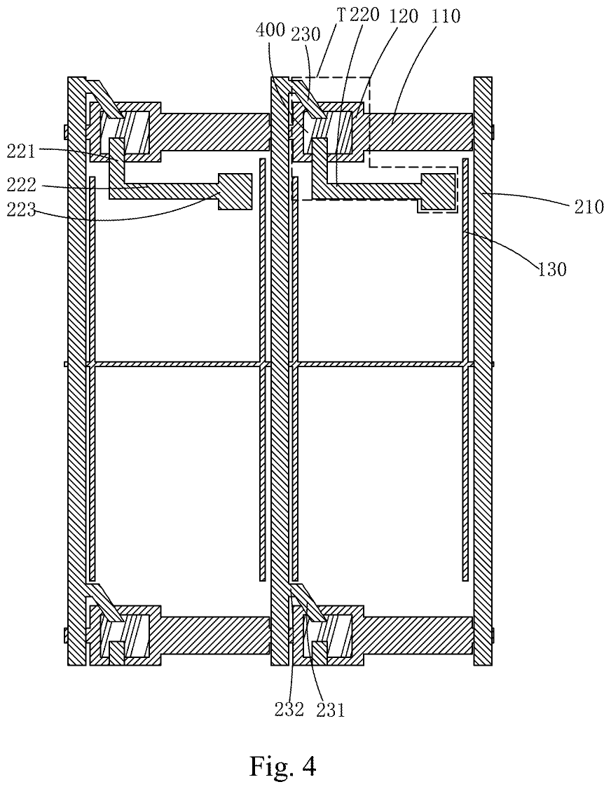

With reference to FIG. 3 and FIG. 4, the present invention provides an array substrate including multiple scanning lines 110 and multiple data lines 210. The multiple scanning lines 110 and the multiple data lines 210 are intersected to form multiple pixel units 1 arranged as a matrix. Each pixel unit 1 includes a thin-film transistor T and a pixel electrode 300. The thin-film transistor T includes a gate electrode 120, a source electrode 220, and a drain electrode 230. The gate electrodes 120 of the thin-film transistors T of a row of the pixel units 1 are correspondingly connected to one scanning line 110. One of the source electrode 220 and the drain electrode 230 of each thin-film transistor T of a column of the pixel units 1 is correspondingly connected to one data line 210, and the other of the source electrode 220 and the drain electrode 230 of each thin-film transistor T is connected to a pixel electrode 300 of the pixel unit 1 through a via hole 901.

In each pixel unit 1, the gate electrode 120 and the via hole 901 of the thin-film transistor T are respectively located at two sides of two adjacent data lines 210 closed to the pixel unit 1.

Specifically, with reference to FIG. 3 and FIG. 4, the thin-film transistor T further includes an active pattern 400. In each thin-film transistors T, the active pattern 400 is disposed on the gate electrode 120, and the source electrode 220 and the drain electrode 230 are respectively connected to two ends of the active pattern 400.

Specifically, in the embodiment shown in FIG. 3 and FIG. 4, in each pixel unit 1, one end of the drain electrode 230 of the thin-film transistor T is connected to one end of the active pattern 400, and the other end is connected to the corresponding data line 210. One end of the source electrode 220 is connected to the other end of the active pattern 400, and the other end extends to one of the two data lines 210 adjacent to the pixel unit 1 away from the gate electrode 120 of the thin-film transistor T, and is connected to the pixel electrode 300 of the pixel unit 1 through the via hole 901.

Furthermore, the source electrode 220 includes a first portion 221, a second portion 222, and a connection end 223 which are sequentially connected. The first portion 221 is connected to the active pattern 400 and extends along a direction parallel to the data line 210. The second portion 222 extends along a direction parallel to the scanning line 110. The via hole 901 corresponds to the connection end 223. The drain electrode 230 includes a third portion 231 and a fourth portion 232 which are sequentially connected. The third portion 231 is connected to the active pattern 400 and extends in a direction away from the active pattern 400. The fourth portion 232 extends along a direction parallel to the scanning line 110 and connects the third portion 231 with the corresponding data line 210.

Specifically, the array substrate includes a first metal layer and a second metal layer disposed above and insulated from the first metal layer. The multiple scanning lines 110 and the gate electrodes 120 of the thin-film transistors T of the multiple pixel units 1 are all located at the first metal layer. The multiple data lines 210 and the source electrodes 220 and the drain electrodes 230 of the thin-film transistors T of the multiple pixel units 1 are both located at the second metal layer.

Furthermore, a common electrode line 130 is further disposed in the first metal layer.

Preferably, a width of an overlapping portion of the scanning line 110 and the data line 210 is less than a width of a portion of the scanning line 110 except the overlapping portion with the data line 210.

It should be noted that, in the array substrate of the present invention, the gate electrode 120 of the thin-film transistor T and the via hole 901 for connecting the thin-film transistor T and the pixel electrode 300 are respectively located at two sides of the two adjacent data lines 210 closed to the pixel unit 1. Both the gate electrode 120 and the via hole 901 are important factors affecting the aperture ratio. With the above structure, the aperture ratio difference between the two sides of the pixel unit 1 is significantly reduced. Without affecting the aperture ratio, the difference in viewing angle due to the difference in aperture ratio is effectively solved, and the display quality is improved. At the same time, the array substrate does not affect the size of the capacitor formed by the source electrode 220 and the gate electrode 120. Thereby, the pixel charging rate has no effect, and the aperture ratio and the transmittance of the pixel are not lost, and the quality of the product is improved.

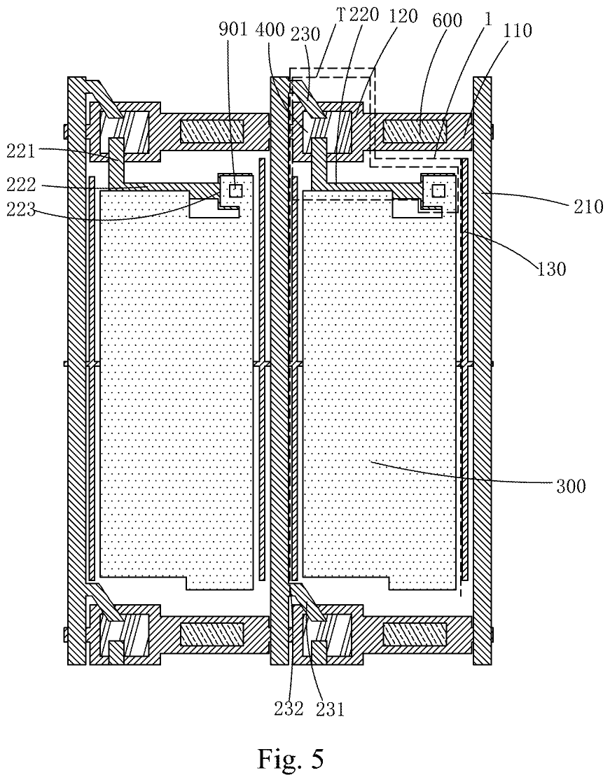

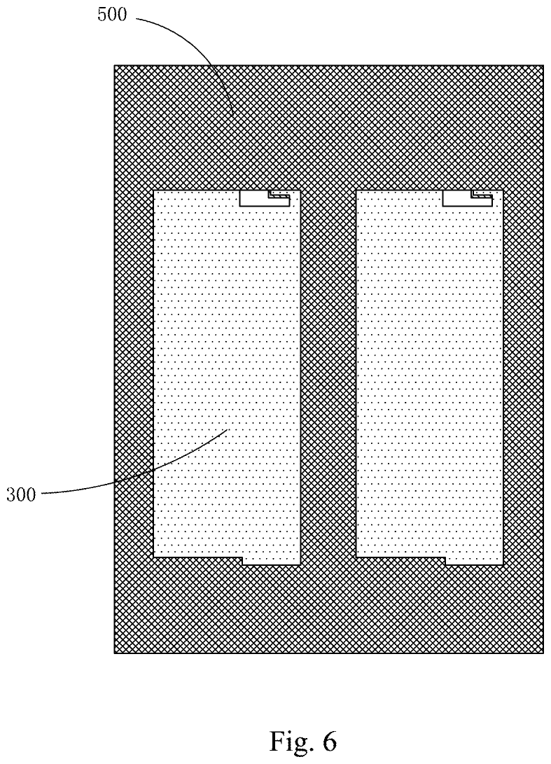

Based on the same inventive concept, with reference to FIG. 5 and FIG. 6, and in conjunction with FIG. 3 and FIG. 4, the present invention further provides a liquid crystal display panel comprising the above array substrate and a color filter substrate disposed opposite to the array substrate. The structure of the array substrate will not be described repeatedly here.

Specifically, the liquid crystal display panel further includes multiple spacers 600 disposed between the array substrate and the color filter substrate, and the multiple spacers 600 correspond to a portion of the scanning lines 110 except a portion overlapped with the data lines 210. A projection of the spacer 600 on the scanning line 110 is located at an inner edge of the scanning line 110, so that the spacer 600 is used to maintain an uniform gap between the array substrate and the color filter substrate, and even the array substrate and the color filter substrate are relative moved, the spacer 600 can also provide a supporting function without any error. The spacer 600 can be formed on the side of the array substrate or on the side of the color filter substrate, and does not affect the realization of the present invention.

Specifically, the color filter substrate includes a black matrix 500, and the black matrix 500 is disposed opposite to the multiple scanning lines 110, the multiple data lines 210, and the multiple thin-film transistors T, and at least partially exposes a connection portion of the thin-film transistor T and the pixel electrode 300.

Specifically, the array substrate is a non-COA type array substrate, and the color fitter substrate further includes a color resist layer (not shown).

It should be noted that, in the array substrate of the present invention, the gate electrode 120 of the thin-film transistor T and the via hole 901 for connecting the thin-film transistor T and the pixel electrode 300 are respectively located at two sides of the two adjacent data lines 210 closed to the pixel unit 1. Both the gate electrode 120 and the via hole 901 are important factors affecting the aperture ratio. With the above structure, the aperture ratio difference between the two sides of the pixel unit 1 is significantly reduced. Without affecting the aperture ratio, the difference in viewing angle due to the difference in aperture ratio is effectively solved, and the display quality is improved. At the same time, the array substrate does not affect the size of the capacitor formed by the source electrode 220 and the gate electrode 120. Thereby, the pixel charging rate has no effect, and the aperture ratio and the transmittance of the pixel are not lost, and the quality of the product is improved.

In summary, in each pixel unit of the array substrate of the present invention, the gate electrode of the thin-film transistor and the via hole for connecting the thin-film transistor and the pixel electrode are respectively located at two sides of the two adjacent data lines closed to the pixel unit. Accordingly, without affecting the aperture ratio, the difference in viewing angle due to the difference in aperture ratio is effectively solved, and the display quality is improved. The liquid crystal display panel of the present invention has a high aperture ratio and can eliminate the difference in viewing angle.

The above is only the preferred embodiment of the present invention, and the scope of the present invention is not limited thereto, and thus equivalent changes made in the claims of the present invention are still within the scope of the present invention.

What is claimed is:

1. An array substrate, comprising:
multiple scanning lines and multiple data lines, wherein the multiple scanning lines and the multiple data lines are intersected to form multiple pixel units arranged as a matrix;
wherein each pixel unit includes a thin-film transistor and a pixel electrode, the thin-film transistor includes a gate electrode, a source electrode, and a drain electrode, the gate electrodes of the thin-film transistors of a row of the pixel units are correspondingly connected to one scanning line, one of the source electrode and the drain electrode of each thin-film transistor of a column of the pixel units is correspondingly connected to one data line, and the other of the source electrode and the drain electrode of each thin-film transistor is connected to a pixel electrode of the pixel unit through a via hole; and
wherein in each pixel unit, the gate electrode and the via hole of the thin-film transistor are respectively located at two sides of two adjacent data lines closed to the pixel unit.

2. The array substrate according to claim 1, wherein the thin-film transistor further includes an active pattern; in each thin-film transistors, the active pattern is disposed on the gate electrode, and the source electrode and the drain electrode are respectively connected to two ends of the active pattern.

3. The array substrate according to claim 2, wherein in each pixel unit, one end of the drain electrode of the thin-film transistor is connected to one end of the active pattern, and the other end is connected to the corresponding data line, one end of the source electrode is connected to the other end of the active pattern, and the other end extends to one of the two data lines adjacent to the pixel unit away from the gate electrode of the thin-film transistor, and is connected to the pixel electrode of the pixel unit through the via hole.

4. The array substrate according to claim 3, wherein the source electrode includes a first portion, a second portion, and a connection end which are sequentially connected; the first portion is connected to the active pattern and extends along a direction parallel to the data line; the second portion extends along a direction parallel to the scanning line; the via hole corresponds to the connection end.

5. The array substrate according to claim 3, wherein the drain electrode includes a third portion and a fourth portion which are sequentially connected; the third portion is connected to the active pattern and extends in a direction away from the active pattern; the fourth portion extends along a direction parallel to the scanning line and connects the third portion with the corresponding data line.

6. The array substrate according to claim 2, wherein the array substrate includes a first metal layer and a second metal layer disposed above and insulated from the first metal layer; the multiple scanning lines and the gate electrodes of the thin-film transistors of the multiple pixel units are all located at the first metal layer; the multiple data lines and the source electrodes and the drain electrodes of the thin-film transistors of the multiple pixel units are both located at the second metal layer.

7. The array substrate according to claim 1, wherein a width of an overlapping portion of the scanning line and the data line is less than a width of a portion of the scanning line except the overlapping portion with the data line.

8. A liquid crystal display panel, comprising:
the array substrate as claimed in claim 1; and
a color filter substrate disposed opposite to the array substrate.

9. The liquid crystal display panel according to claim 8, wherein the color filter substrate includes a black matrix, and the black matrix is disposed opposite to the multiple scanning lines, the multiple data lines, and the multiple thin-film transistors, and at least partially exposes a connection portion of the thin-film transistor and the pixel electrode.

10. The liquid crystal display panel according to claim 8, wherein the liquid crystal display panel further includes multiple spacers disposed between the array substrate and the color filter substrate, and the multiple spacers correspond to a portion of the scanning lines except a portion overlapped with the data lines; a projection of the spacer on the scanning line is located at an inner edge of the scanning line.
